(19) United States
(12) Patent Application Publication
(10) Pub. No.: US 2006/0205152 A1
(43) Pub. Date: Sep. 14, 2006

(54) Method of fabricating flash memory device

(75) Inventor: Hyeon Sang Shin, Icheon-si (KR)

Correspondence Address: MAYER, BROWN, ROWE & MAW LLP, 1909 K STREET, N.W., WASHINGTON, DC, 20006, US

(73) Assignee: Hynix Semiconductor Inc.

(21) Appl. No.: 11/174,629

(22) Filed: Jul. 6, 2005

(30) Foreign Application Priority Data
Mar. 10, 2005 (KR) 2005-20213

(51) Int. Cl. H01L 21/336

(52) U.S. Cl. 438/257

(57) ABSTRACT

The present invention relates to a method of fabricating a flash memory device. The width of an active region (line) is reduced, but the width of a field region (space) is extended. An overlay margin between the floating gates and the active region depending upon increase in the level of integration of a device can be improved. A channel is formed not only an active region but also sidewalls of trenches at both sides of the active region, thus extending an effective channel length. It is thus possible to compensate for a reduction in the cell current depending upon a reduction of the width of the active region (line).

### BACKGROUND

1. Field of the Invention

The present invention relates to a flash memory device, and more specifically, to a method of fabricating a flash memory device, which is suited for compensating for a reduction in cell current depending upon a reduction in an active width due to higher integration.

2. Discussion of Related Art

As well noted, a flash memory device is a device, which is fabricated by taking advantages of an EPROM having programming and erase characteristics and an EEPROM having electrical programming and erase characteristics.

This flash memory device is adapted to realize the storage state of one bit as through one transistor, and performs electrical programming and erase.

A flash memory cell generally has a structure in which a tunnel dielectric film, a floating gate, an interlayer dielectric film and a control gate are formed on a silicon substrate. In the flash memory cell having this structure, data are stored in such a manner that electrons are injected or extracted into or from the floating gate by applying a predetermined voltage to the control gate and the substrate.

In the flash memory device, as the design rule is lowered below 70 nm, the accuracy that is actually required becomes lower than an overlay accuracy limit of a lithography apparatus. Due to this, the flash memory device inevitably adopts a self-aligned floating gate (hereinafter, referred to as “SAFG”) structure in which the floating gate is formed on an isolation trench that is already formed on a substrate in a self-aligned manner.

The SAFG structure is fabricated by forming a trench in a semiconductor substrate having a pad oxide film and a silicon nitride film formed in, burying the trenches to form an isolation film, performing a wet etch process on the silicon nitride film and the pad oxide film, intervening a tunnel dielectric film into a portion where the silicon nitride film and the pad oxide film are wet-etched, forming a floating gate, and sequentially stacking an interlayer dielectric film and a control gate on the floating gate.

Thereafter, in a gate etch process, in order to strip the control gate and the interlayer dielectric film buried between the floating gates, a distance between the floating gates has to be kept over 50 nm in case of a 60 nm flash memory device. As a result, although an active critical dimension (hereinafter, referred to as “CD”) has 50 nm, an overlay margin between the active CD and the floating gate becomes 60×2 nm−50 nm (distance between floating gates)−50 nm (active CD)=20 nm, where 10 nm per one side.

If variations of final inspection critical dimension (FICD) and a series of wet processes for implementing the SAFG after a patterning process for element isolation are considered, however, the overlay margin has almost a limit value. It is thus necessary to improve the margin by making the active CD about 40 nm. If the active CD reduces, however, there is a problem in that the cell current reduces.

### SUMMARY OF THE INVENTION

Accordingly, the present invention has been made in view of the above problems, and it is an object of the present invention to provide a method of fabricating a flash memory device, wherein the overlay margin between an active region and a floating gate can be enhanced.

Another object of the present invention is to provide a method of fabricating a flash memory device, wherein a reduction in the cell current depending upon a reduction in an active CD can be compensated for.

To achieve the above objects, according to the present invention, there is provided a method of fabricating a flash memory device, including the steps of forming a pad oxide film and a pad nitride film on a semiconductor substrate, forming trenches in the pad nitride film, the pad oxide film and the semiconductor substrate to define an active region and a field region, forming element isolation films within the trenches, removing the pad nitride film, removing the sides of the element isolation films by a predetermined thickness while removing the pad oxide film, thus exposing the semiconductor substrate of the active region and the semiconductor substrate on upper sides of the trenches at both sides of the active region, forming a channel region within the exposed semiconductor substrate, forming a tunnel dielectric film having a constant thickness on the semiconductor substrate in which the channel region is formed, and forming floating gates on the tunnel dielectric film.

Upon formation of the trenches, the width of the field region is preferably greater than that of the active region.

The width of the active region is preferably 0.5 times smaller than that of the field region.

The trenches are preferably formed by forming a photoresist pattern on the pad nitride film, and etching the pad nitride film, the pad oxide film and the semiconductor substrate using the photoresist pattern as a mask.

The photoresist pattern is preferably formed to open the entire field region, and a recipe that does not generate CD loss is used when the pad nitride film is etched.

The photoresist pattern is preferably formed to open some of the field region, and a recipe that generates CD loss is used when the pad nitride film is etched.

The method can further include the step of forming a sidewall oxide film in the semiconductor substrate in which the trenches are formed, after the trenches are formed.

A thickness that the sides of the element isolation films are preferably removed is 100 to 300 Å per side.

The channel region is preferably formed by implanting a cell threshold voltage ion at a tilt.

The tunnel dielectric film is preferably an oxide film formed by means of a radical oxidization process.

The method can further include the step of removing the element isolation films between the floating gates to expose the sides of the floating gates, after the floating gates are formed.

When the element isolation films are removed, a wet etch process can be used.

### BRIEF DESCRIPTION OF THE DRAWINGS

FIGS. 1a to 1c are cross-sectional views showing process steps for manufacturing a flash memory device according to an embodiment of the present invention.

### DETAILED DESCRIPTION OF PREFERRED EMBODIMENTS

Now, the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later.

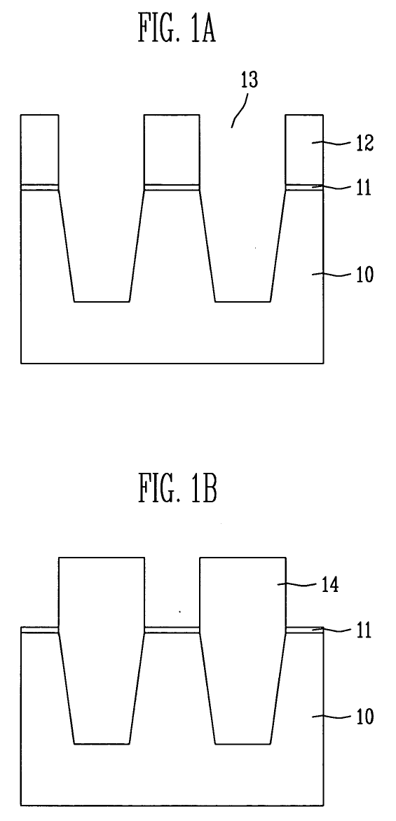

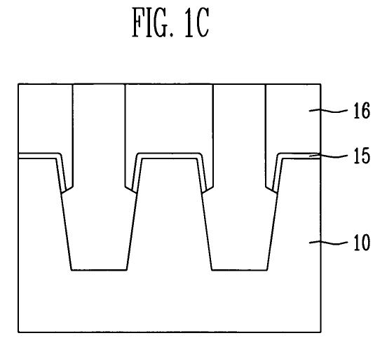

FIGS. 1a to 1c are cross-sectional views showing process steps for manufacturing a flash memory device according to an embodiment of the present invention.

A well process, an implant process such as a cell implant process, and the like are performed on a semiconductor substrate 10. As shown in FIG. 1a, a pad oxide film 11 is formed on the semiconductor substrate 10. A pad nitride film 12 is deposited on the pad oxide film 11 to a thickness necessary to secure the height of a floating gate.

The pad nitride film 12, the pad oxide film 11 and the semiconductor substrate 10 are selectively etched by means of a patterning process for forming element isolation films, thus forming trenches 13 whereby an active region (line) and a field region (space) are defined.

That is, a photoresist pattern (not shown) that defines the field region is formed. The pad nitride film 12, the pad oxide film 11 and the semiconductor substrate 10 are etched using the photoresist pattern as an etch mask, thereby forming the trenches 13.

The width ratio of the field region (space) and the active region (line) was 1:1 in the prior art. In the present invention, however, the width of the field region (space) is made greater than that of the active region (line) in order to secure an overlay margin between the floating gate and the active region. It is preferred that the width of the active region (line) is 0.5 smaller than that of the field region (space).

For example, in case of a 60 nm flash memory device, in the prior art, both the widths of the active region (line) and the field region (space) are formed to be 60 nm. In the present invention, however, the width of the field region (space) is formed to be 80 nm and the width of the active region (line) is formed to be 40 nm.

As in the present invention, in order to extend the width of the field region (space) but reduce the width of the active region (line), a method in which the final inspection critical dimension (hereinafter, referred to as “FICD”) being a final etch pattern is made small by shrinking the develop inspection critical dimension (hereinafter, referred to as “DICD”) of a photoresist pattern or a method in which the FICD is reduced using a recipe that generates CD loss upon etching of the pad nitride film 12 without reducing the DICD of the photoresist pattern can be used.

A sidewall oxide film (not shown) is then formed on the surface of the semiconductor substrate 10 in which the trenches 13 are formed by means of a sidewall oxidation process.

Thereafter, as shown in FIG. 1b, the trenches 13 are gap-filled with a high aspect ratio planarization (hereinafter, referred to as “HARP”) film. The HARP film is polished by means of a chemical mechanical polishing (hereinafter, referred to as “CMP) so that the pad nitride film 12 is exposed, thus forming element isolation films 14 within the trenches 12.

The pad nitride film 12 is then removed by means of a phosphoric acid (H₃PO₄) process.

As a result of removing the pad nitride film 12, portions of the element isolation films 14, which are projected over the top surface of the semiconductor substrate 10, are exposed.

As shown in FIG. 1c, the pad oxide film 11 is then stripped by means of a pre-cleaning process, exposing the semiconductor substrate 10 of an active region. In this case, the sides of the element isolation films 14 are also removed by a predetermined thickness, so that lateral top sides of the semiconductor substrate 10 in which the trenches 13 are formed at both sides of the active region are exposed.

That is, if the pre-cleaning process is performed to completely remove the pad oxide film 11, the element isolation films 14 are etched by means of a cleaning solution of the pre-cleaning process. Thus, not only the semiconductor substrate 10 of the active region, but also the lateral top sides of the semiconductor substrate 10 in which the trenches 13 are formed at both sides of the active region are exposed.

In this case, the element isolation films 14 are preferably removed to a thickness of about 100 to 300 Å per-side.

Next, a cell threshold (Vt) voltage ion is implanted into the exposed semiconductor substrate 10, thus forming a channel region.

The cell threshold voltage ion is also tilt-implanted into the sidewalls of the semiconductor substrate 10 in which the trenches 13 are formed in order to use them as the channel region simultaneously with the above cell threshold voltage ion.

Therefore, the channel region is formed not only in the active region, but also in the sidewall of the semiconductor substrate 10 having the trenches 13 formed in at both sides of the channel region. Thus, as an effective channel length increases, a reduction in the cell current depending upon a reduction in the width of the active region can be compensated for.

Thereafter, a tunnel dielectric film 15 having a regular thickness is formed on the surface of the semiconductor substrate 10 in which the channel regions are formed.

In order to form the tunnel dielectric film 15 having a constant thickness not only on the surface of the semiconductor substrate 10 of the active region but also on the corners and sidewalls of the trenches 13, an oxide film formed by means of a radical oxidization process is preferably used as the tunnel dielectric film 15.

As the radical oxidization process is used when forming the tunnel dielectric film 15, it is possible to form the tunnel dielectric film 15 having a constant thickness not only on the surface of the semiconductor substrate 10 of the active region but also on the corners and sidewalls of the trenches 13.

A first polysilicon film is then formed on the entire surface. The first polysilicon film is polished by means of CMP so that the element isolation films 14 are exposed, thus forming floating gates 16 which are separated with the element isolation films 14 therebetween.

Though not shown in the drawings, the element isolation films 14 between the floating gates 16 are removed by a desired target by means of a wet etch process. Thereby, while the sides of the floating gates 16, which are in contact with the element isolation films 14, are exposed, the exposed area of the floating gates 16 is increased to enhance the coupling ratio.

Though not shown in the drawings, an interlayer dielectric film and a control gate are formed on the floating gates 16 and the element isolation films 14. The control gate and the interlayer dielectric film are etched by means of a gate patterning process, and the floating gates 16 are patterned by means of a self-aligned etch process using the patterned control gate.

Manufacturing of the flash memory device according to the present invention is thereby completed.

As described above, the present invention has the following effects.

Since the width of an active region reduces, the width of a field region between the active regions can be extended. It is thus possible to improve an overlay margin between floating gates and the active region.

An effective channel length can be extended by forming a channel region on sidewalls of trenches as well as both sides of an active region. It is therefore possible to prevent a reduction of the cell current depending upon a reduction in the width of the active region.

Although the foregoing description has been made with reference to the preferred embodiments, it is to be understood that changes and modifications of the present invention may be made by the ordinary skilled in the art without departing from the spirit and scope of the present invention and appended claims.

What is claimed is:

1. A method of fabricating a flash memory device, comprising the steps of:
forming a pad oxide film and a pad nitride film on a semiconductor substrate;
forming trenches in the pad nitride film, the pad oxide film and the semiconductor substrate to define an active region and a field region;
forming element isolation films within the trenches;
removing the pad nitride film;
removing the sides of the element isolation films by a predetermined thickness while removing the pad oxide film, thus exposing the semiconductor substrate of the active region and the semiconductor substrate on upper sides of the trenches at both sides of the active region;
forming a channel region within the exposed semiconductor substrate;
forming a tunnel dielectric film having a constant thickness on the semiconductor substrate in which the channel region is formed; and
forming floating gates on the tunnel dielectric film.

2. The method as claimed in claim 1, wherein upon formation of the trenches, the width of the field region is greater than that of the active region.

3. The method as claimed in claim 2, wherein the width of the active region is 0.5 times smaller than that of the field region.

4. The method as claimed in claim 1, wherein the trenches are formed by forming a photoresist pattern on the pad nitride film, and etching the pad nitride film, the pad oxide film and the semiconductor substrate using the photoresist pattern as a mask.

5. The method as claimed in claim 4, wherein the photoresist pattern is formed to open the entire field region, and a recipe that does not generate CD loss is used when the pad nitride film is etched.

6. The method as claimed in claim 4, wherein the photoresist pattern is formed to open some of the field region, and a recipe that generates CD loss is used when the pad nitride film is etched.

7. The method as claimed in claim 1, further including the step of forming a sidewall oxide film in the semiconductor substrate in which the trenches are formed, after the trenches are formed.

8. The method as claimed in claim 1, wherein a thickness that the sides of the element isolation films are removed is 100 to 300 Å per side.

9. The method as claimed in claim 1, wherein the channel region is formed by implanting a cell threshold voltage ion at a tilt.

10. The method as claimed in claim 1, wherein the tunnel dielectric film is an oxide film that is formed by means of a radical oxidization process.

11. The method as claimed in claim 1, further including the step of removing the element isolation films between the floating gates to expose the sides of the floating gates, after the floating gates are formed.

12. The method as claimed in claim 11, wherein when the element isolation films are removed, a wet etch process is used.
